(19) United States
(12) Patent Application Publication
(10) Pub. No.: US 2002/0000605 A1
(43) Pub. Date: Jan. 3, 2002

(54) Method of fabricating high-coupling ratio split gate flash memory cell array

(76) Inventors: Chun-Mai Liu, San Jose, CA (US); Kung-Yen Su, San Jose, CA (US); Albert V. Kordesch, San Jose, CA (US); Ping Guo, San Jose, CA (US)

Correspondence Address: OPPENHEIMER WOLFF & DONNELLY, P. O. BOX 10356, PALO ALTO, CA, 94304, US

(21) Appl. No.: 09/827,056

(22) Filed: Apr. 3, 2001

Related U.S. Application Data
(60) Provisional application No. 60/214,835, filed on Jun. 28, 2000.

(51) Int. Cl. H01L 29/788

(52) U.S. Cl. 257/316; 438/266

(57) ABSTRACT

A method of fabricating a flash memory device including an array of split gate cells, comprising the steps of: providing a silicon substrate having a top surface; implanting ions into a predefined area of the substrate to form a common source region of the substrate; forming at least one floating gate over the substrate, each floating gate being associated with one of the cells and having a portion which overlies a portion of the common source region, the overlying portion of each floating gate providing for a high coupling ratio for the associated flash cell; forming a select gate over at least a portion of each floating gate; and forming a drain region associated with each cell. The high coupling ratio flash cell device of the present invention overcomes limitations associated with conventionally formed split gate flash cells by forming the common source region first and then forming the floating gates over the common source region in order to provide a high coupling ratio for the cells.

### CROSS REFERENCE TO RELATED APPLICATIONS

Reference is made and priority claimed to U.S. Provisional Patent Application No. 60/214,835, filed on Jun. 28, 2000.

### BACKGROUND OF THE INVENTION

1. Field of the Invention

The present invention relates generally to semiconductor memory devices, and more specifically to a high-coupling-ratio split gate flash cell memory device and a process of manufacturing such a device.

2. Description of the Prior Art

An electrically erasable programmable memory (EEPROM) cell is a nonvolatile writable and erasable memory cell which requires very low operating currents. The unit cell of an EEPROM may be formed by connecting a memory transistor in series with a select transistor. Some EEPROM designs are integrated so that the features of the two transistors are merged. Flash EEPROMs describe a family of single-transistor cell EEPROMs. Cell sizes of Flash EEPROMs are about half that of two transistor EEPROMs.

Flash memory designs differ in their cell structure based on whether they require one or several transistors per cell. A split-gate flash cell provides the equivalent of a two-transistor architecture, but requires only slightly more semiconductor real-estate than a single transistor cell. Through a diffusion process, the split-gate creates a phantom transistor that looks like a series transistor. This allows the cell to be isolated from other cells in a column.

FIG. 1 shows a cross sectional view of a conventional split gate flash memory device at 10, the memory device including first and second memory cells at 12 and 14. The memory device 10 is manufactured in accordance with a conventional semiconductor fabrication process including the steps of: forming a tunneling oxide layer 16, 18 over a substrate 20; forming a polysilicon layer 22, 24 over the tunneling oxide layer 16, 18; and forming a floating gate oxide layer 26, 28 over portions of the polysilicon layer 22, 24 which are to provide floating gates. Subsequently portions of the polysilicon layer 22, 24 and tunneling oxide layer 16, 18 are removed by an etching process using the floating gate oxide layer 26, 28 as a mask, thereby exposing portions of the substrate 20 and forming first and second floating gates 22 and 24 from the remaining portions of the first polysilicon layer. Subsequently an insulating layer 30, 32 is formed over the exposed portions of the substrate 20, over the floating gates 22 and 24, and over the floating gate oxide layer 26, 28. A conductive layer 34, 36 is then deposited over the insulating layer 30, 32. A patterning and etching process is performed to remove portions of the insulating layer 30, 32 and portions of the conductive layer 34, 36, thereby exposing portions of the substrate 20, and forming first and second select gates 34 and 36 from remaining portions of the conductive layer. Drain regions 38 and 40 are formed by performing a gas deposition process to dope portions of substrate 20.

A common source region 42 is formed in accordance with a gas deposition process illustrated at 44 which includes depositing ions into the exposed portion of the substrate 20 between the floating gates 22 and 24. Typically phosphorus ions are deposited to form the source region 42. During the deposition process, ions diffuse downward into the substrate 20 and laterally to extend outward from the exposed portion of the substrate to areas of the substrate disposed beneath floating gates 22 and 24. This lateral diffusion of ions is referred to as side diffusion. The process of forming a common source region in this manor is referred to a as source side injection process. For gas diffusion, the distance that the side diffusion can extend laterally is limited to approximately 70% of the diffusion depth, which is the distance that ions may be diffused downward into the substrate. Because the diffusion depth is limited, the side diffusion of ions beneath the floating gates 22 and 24 is also limited to distances shown at 46, which are referred to herein as side diffusion distances.

One problem with conventional split gate flash memory devices wherein the common source region is formed in accordance with a side diffusion process as described above, is that considerable time and higher voltage is required to program each flash cell. Faster programming times and lower programming voltages are desirable in flash memory devices. Programming a flash cell 12, 14 includes transferring charge from the drain regions 38, 40 to the associated floating gate 22, 24. The time and voltage required to charge the floating gate 22, 24 is dependent on the coupling ratio K_{cs} of the flash cell which is defined as the ratio of C_{fg-cs}/C_{TOT}, where C_{fg-cs} is the capacitance between floating gate 22, 24 and the source region 42, and C_{TOT} is the total capacitance of the floating gate 22, 24. Kcs is therefore related to the ratio of the area of the associated floating gate 22, 24 to the area of the portion of the common source region 42 disposed beneath the associated floating gate. A higher coupling ratio K_{cs} provides for a shorter programming time and lower programming voltage for a split gate flash cell. The coupling ratio K_{cs} is proportional to the side diffusion distance 46 that the common source region 42 extends beneath the floating gate 22, 24. As discussed above, the side diffusion distance 46 is limited because the maximum allowable diffusion depth of the common source region 42 is limited, and because the side diffusion distance is limited to 70% of the diffusion depth.

Another problem with conventional split gate flash memory devices is that a high programming voltage is required. Lower programming voltages are desirable for split gate flash memory devices. A mathematical formula for the programming function is presented below in Relationship (1).

V_{FG}=Q_{FG}/C_{TOT}+K_{G}V_{CG}+K_{CS}V_{CS}+K_{C}V_{C} (1)

Where V_{FG} is the floating gate voltage; Q_{FG} is the charge on the floating gate; C_{TOT} is the total capacitance associated with the floating gate; K_{G} is the control gate coupling ratio; V_{CG} is the control gate voltage; K_{CS} is the source side coupling ratio; V_{CS} is the applied source side voltage; K_{C} is the virtual source channel coupling ratio; and V_{C} is the virtual source channel voltage.

The programming voltage for a split gate flash cell is proportional to the applied source side voltage V_{CS} which can be reduced by increasing the source side coupling ratio K_{CS}. Unfortunately the source side coupling ratio K_{CS} of a flash cell formed in accordance with the conventional source side injection process described above is limited by the side diffusion of dopants as discussed above. Due to the limitations of the side diffusion of phosphorus, the source side coupling ratio K_{CS} is limited to a value of approximately 0.5 where phosphorous is used to form the common source region.

Another problem with a split gate flash cell formed in accordance with the conventional source side injection process is that the threshold voltage between the common source region 42 and the drain regions 38 and 40 cannot be adjusted. The need to fabricate a split gate flash cell such that it has a precise threshold voltage requires a more precise fabrication process than would be required if threshold voltages could be adjusted by other means.

What is needed is a method of fabricating a split gate flash memory device including cells having an increased coupling ratio thereby reducing the time and voltage required to program each cell.

### SUMMARY OF THE INVENTION

It is an object of the present invention to provide a method of fabricating a split gate flash memory device, including cells having an increased coupling ratio thereby reducing the time and voltage required to program each cell.

It is a further object of the present invention to provide a process for manufacturing a flash semiconductor memory device including a pair of memory cells sharing a common source region, wherein threshold voltages are adjustable by doping the channel region.

Briefly, a presently preferred embodiment of the present invention provides a process of fabricating a flash memory device including an array of split gate cells, comprising the steps of: providing a silicon substrate having a top surface; implanting ions into a predefined region of the substrate to form a common source region of the substrate; forming at least one floating gate over the substrate, each of the floating gates being associated with one of the cells and having a portion which overlies a portion of the common source region, the overlying portion providing for a high coupling ratio for the associated flash cell; forming at least one select gate over at least a portion of the floating gate; and forming a drain region associated with each cell.

In another embodiment of the present invention additional ions are implanted into portions of the substrate defined by the area to be occupied by the floating gates, whereby threshold voltages of the flash memory cells are adjusted.

As described above, conventional process split gate flash cells are manufactured by forming floating gates and subsequently performing an ion implant process to form the common source region. Forming the floating gates before forming the common source region disposed beneath them inherently limits the area which the common source region may extend beneath the floating gates and therefore limits the coupling ratio K_{cs}. The high coupling ratio flash cell device of the present invention overcomes this limitation in coupling ratio by forming the common source region first and then forming the floating gates over the common source region in order to provide a high coupling ratio for the cells.

One advantage of the process of the present invention is that it provides for fabricating a split gate flash memory device including cells having an increased coupling ratio thereby reducing the time and voltage required to program each cell.

Another advantage of the present invention is that it provides a process for manufacturing a flash semiconductor memory device including a pair of memory cells sharing a common source region, wherein threshold voltages are adjustable by doping the channel region.

The foregoing and other objects, features, and advantages of the present invention will be apparent from the following detailed description of the preferred embodiment which makes reference to the several figures of the drawing.

### IN THE DRAWINGS

FIG. 1 is a cross sectional view of a conventional semiconductor memory device including a pair of memory cells each having a floating gate having a portion which is formed over a common source region, the device being manufactured in accordance with a conventional fabrication process wherein the floating gates are formed initially and wherein the portion of the source region disposed below the floating gates is subsequently formed by an ion implant process which limits the coupling ratio of the cells;

FIGS. 2A through 2H are cross-sectional views generally illustrating a progression of fabrication steps in accordance with a process of manufacturing a memory device in accordance with the present invention;

FIG. 3 is a cross sectional view of an embodiment of a high coupling ratio flash memory device in accordance with the present invention; and

FIG. 4 is a top view of an embodiment of a high coupling ratio flash memory device in accordance with the present invention.

### DETAILED DESCRIPTION OF THE PREFERRED EMBODIMENTS

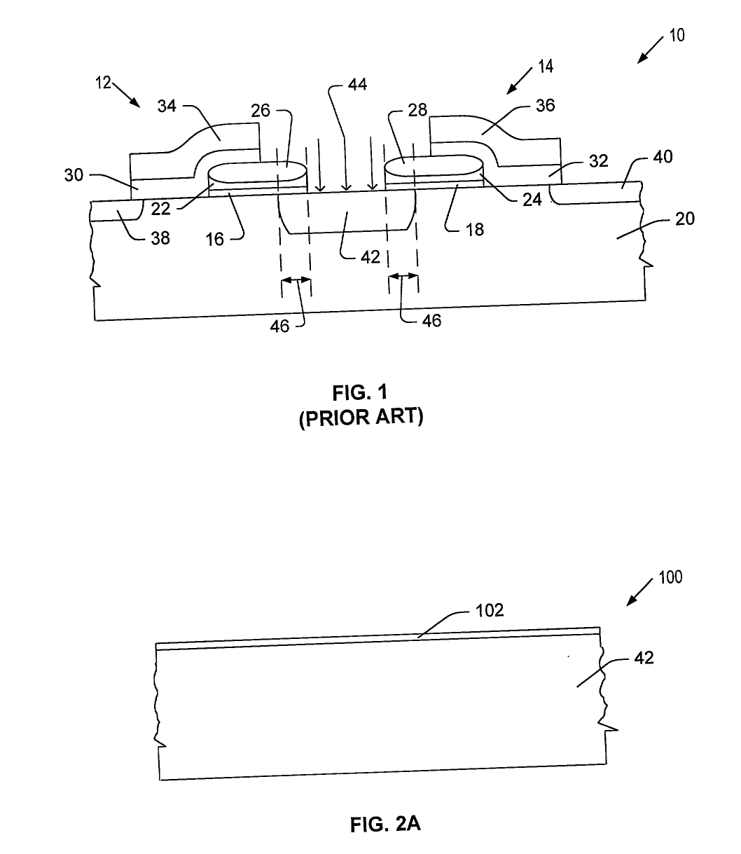

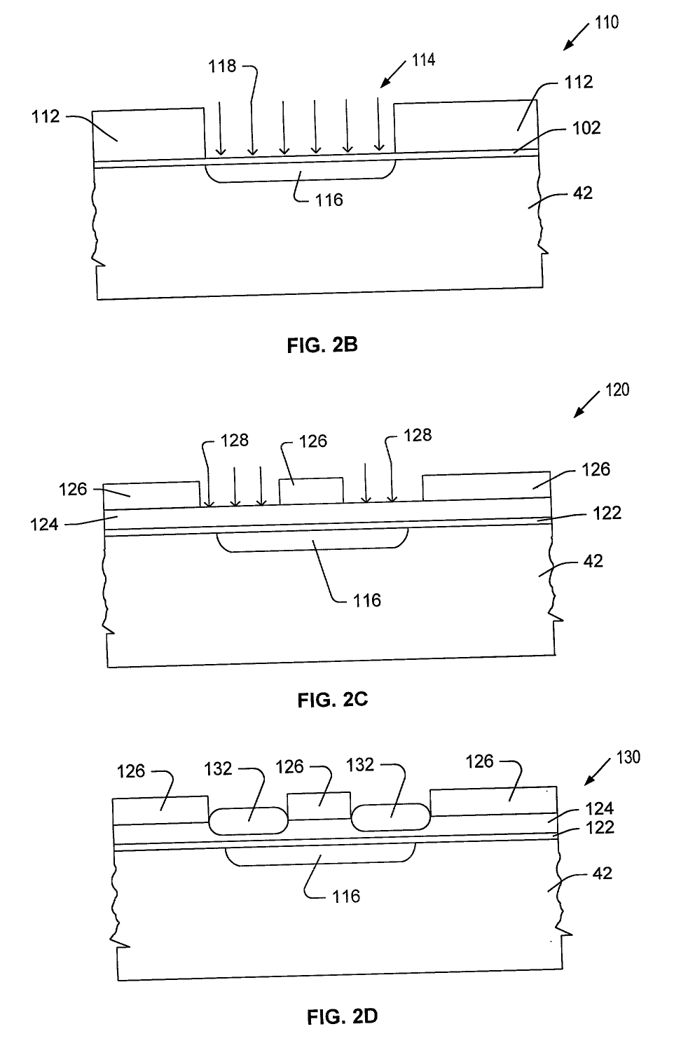

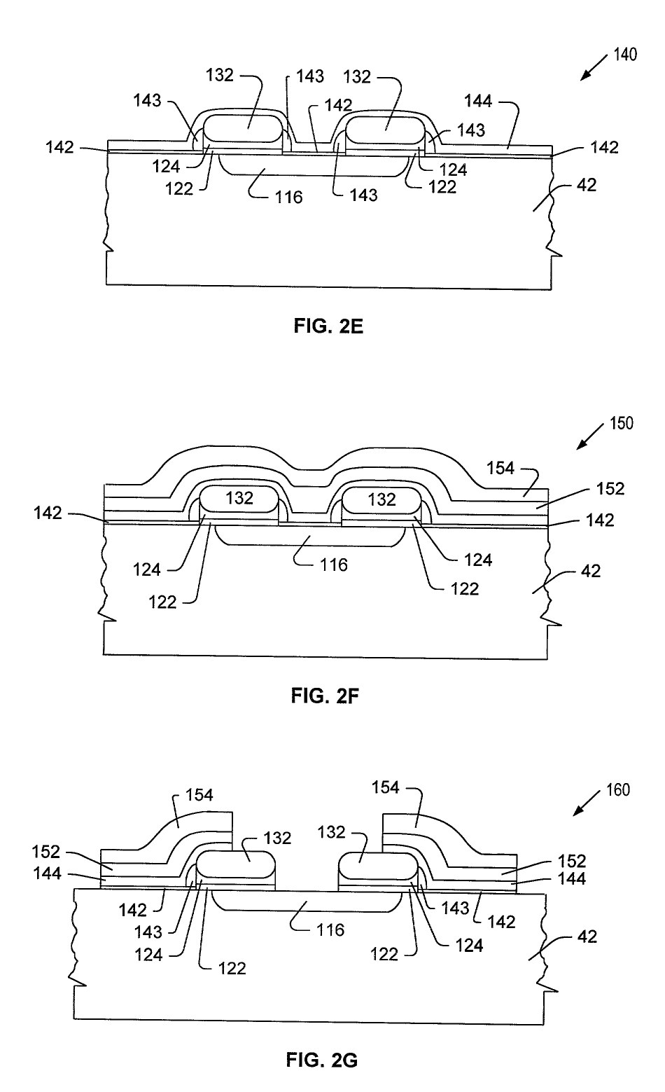

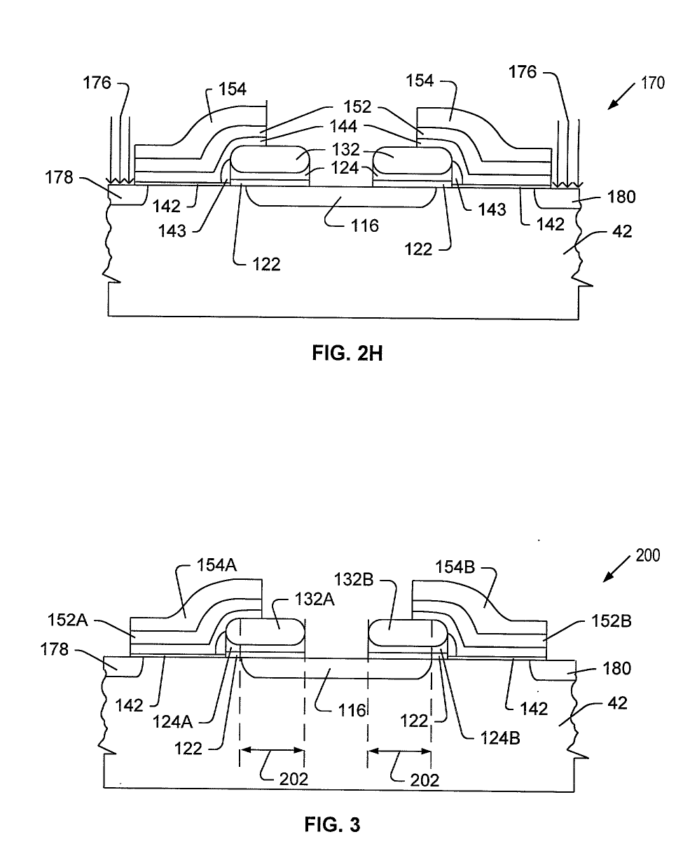

FIGS. 2A through 2G show cross-sectional views generally illustrating a progression of fabrication steps in accordance with a process of manufacturing a high coupling ratio split gate flash memory device in accordance with the present invention.

Referring to FIG. 2A, a silicon substrate 42 is subjected to a localized oxidation of silicon (LOCOS) process to form a sacrificial oxide layer 102 on the top surface of the substrate 42. In accordance with one embodiment of the present invention, the sacrificial oxide layer 102 has a thickness in the approximate range of 200 to 450 angstroms.

Referring to FIG. 2B, a photoresistive masking layer 112 is formed over the sacrificial oxide layer 102, the masking layer 112 substantially defining a source region 114 of the substrate. A first ion implantation step is performed to implant first ions 118 in the source region 114 proximate the top surface of the substrate 42 using the photoresistive masking layer 112 as an implantation mask resulting in the formation of common source region 116. In one embodiment of the present invention, the first ions 118 include arsenic (As⁺) ions implanted to provide a dopant density in the approximate range of 1×10¹⁴/cm² to 5×10¹⁴/cm² and at an approximate energy range of 80 to 150 Kev. As further explained below, the extended common source region 116 provides a source for multiple flash memory cells. Performance of the arsenic ion implantation of the above discussed embodiment results in the common source region 116 being an N+ type region. After the ion implant process is complete, the photoresist layer 112 and the sacrificial oxide layer 102 are removed to expose the top surface of the substrate 42 including the source region 116.

Referring to FIG. 2C, a shallow tunneling oxide layer 122 is formed over the exposed top surface of the substrate 42. In one embodiment of the present invention, the oxide layer 122 is formed in accordance with an oxidation process controlled at a temperature of approximately 900 degrees C. in order to provide a thickness of the layer 122 in the approximate range of 50 to 150 angstroms. Subsequently a first polysilicon layer 124 is deposited over the tunneling oxide layer 122. In one embodiment, SiH4 gas is used in a deposition process controlled at a temperature of approximately 620 degrees C. in order to form the first polysilicon layer 124 to have a thickness in the approximate range of 500 to 2500 angstroms. A nitride masking layer 126 is formed over the polysilicon layer 124. The nitride layer 126 is patterned and etched in order to expose portions of the first polysilicon layer 124.

A second ion implantation process is performed as shown in FIG. 2C, wherein second ions 128 are implanted into portions of the substrate 42 using a photoresist mask (not shown) as an implantation mask. In accordance with one embodiment of the present invention, boron ions are implanted at a concentration in the approximate range of 1.0×10¹¹/cm² to 1.0×10¹³/cm² and at an energy level in the approximate range of 80 KeV to 160 KeV. This boron implanted region functions to adjust the threshold voltage of the cells channel voltage. As is generally understood by those of ordinary skill in the art of semiconductor manufacturing, additional ion implantation processes may be necessary to adequately adjust threshold voltages associated with the memory cells to be formed. Such additional ion implantation processes may be performed at various locations and various stages of the manufacturing process.

Referring to FIG. 2D, a floating gate oxide layer 132 is formed over the exposed portions of the first polysilicon layer 124 as shown. In one embodiment, the floating gate oxide layer 132 is formed in accordance with an oxidation process controlled at a temperature in the approximate range of 800 to 1000 degrees C. in order to provide a thickness in the approximate range of 1000 to 3000 angstroms. Subsequently the nitride masking layer 126 and photoresist mask (not shown) are removed. Typically the nitride masking layer 126 and the photoresist mask (not shown) are stripped away with hot acid.

Referring to FIG. 2E, the first polysilicon layer 124 (FIG. 2D) and tunneling oxide layer 122 (FIG. 2D) are etched using the floating gate oxide layer 132 as a mask leaving remaining portions of the first polysilicon layer 124 and the tunneling oxide layer 122 disposed beneath the floating gate oxide layer 132, and exposing a portion of the substrate 42. Each remaining portion of the first polysilicon layer 124 forms a floating gate 124 associated with each cell having side walls and also having a portion which overlies a portion of the common source region 116 thereby providing a high coupling ratio for said associated cell.

A first gate oxide layer 142 is then formed over the exposed portions of the silicon substrate 42, over a portion of the floating gates 124 and over the floating gate oxide layer 132. In one embodiment, the first gate oxide layer 142 is formed in accordance with an oxidation process controlled at a temperature of approximately 950 degrees C. in order to provide a thickness in the approximate range of 20 to 200 angstroms.

A nitride layer is deposited over the first gate oxide layer 142. Subsequently a portion of the nitride layer is etched away by performing an etching process leaving nitride spacers 143 adjacent the side walls of each floating gate 124. In accordance with one embodiment of the present invention the nitride spacers 143 have a thickness in the approximate range of 15 to 150 angstroms.

A second gate oxide layer 144 is formed over the exposed portions of the first gate oxide layer 142, nitride spacers 143 and floating gate oxide layers 132, to form the structure shown in FIG. 2E. In accordance with one embodiment of the present invention, the second gate oxide layer is formed in accordance with an oxidation process controlled at a temperature of approximately 950 degrees C. in order to provide a thickness in the approximate range of 120 to 300 angstroms.

Referring to FIG. 2F, a second polysilicon layer 152 is formed over the second gate oxide layer 144. In one embodiment, the second polysilicon layer has a thickness in the approximate range of 1500 to 2000 angstroms. Subsequently a conductive layer 154 is deposited over the second polysilicon layer 152 forming the structure shown in FIG. 2F. In one embodiment of the present invention, the conductive layer 154 includes tungsten. In alternative embodiments of the present invention, the conductive layer 154 may include any appropriate conductive material.

Referring to FIG. 2G, portions of the conductive layer 154, the second polysilicon layer 152, the second gate oxide layer 144, the nitride spacers 143, and the first gate oxide layer 142 are etched away, exposing portions of the floating gate oxide layer 132, portions of the side walls of the floating gates 124, portions of the tunneling oxide layer 122 and portions of the substrate 42 forming the structure shown.

Referring to FIG. 2H, a mask (not shown) is formed over the conductive layer 154, portions of the floating gate oxide layer 132 and portions of the substrate 42 in order to define floating gate regions. Subsequently the exposed portion of the substrate 42 is subjected to a third ion implantation process illustrated at 176 using the mask (not shown) as an implantation mask in order to form drain regions 178 and 180. In one embodiment of the present invention, N+ ions are implanted in a third ion implantation process resulting in the drain regions 178 and 180 being N+ type regions.

FIG. 3 shows a completed high coupling ratio flash memory device manufactured in accordance with the process of the present invention. The device at 200 includes two flash memory cells sharing the common source region 116. A first cell is associated with the first drain region 178 and includes a select gate made up of conductive layer 154A and second polysilicon layer 152A. This first cell is programmed by charging the floating gate 124A.

The device 200 provides cells having an increased source side coupling ratio relative to the prior art. This increased source side coupling ratio is due to the distance 202 the source region 116 extends beneath the floating gate 124A, 124B being increased over the distance 46 the prior art source region 42 (FIG. 1) extends beneath floating gate 22, 24 (FIG. 1). This increase in the distance the source region 116 extends beneath the floating gate 124A, 124B is provided by the method of the present invention.

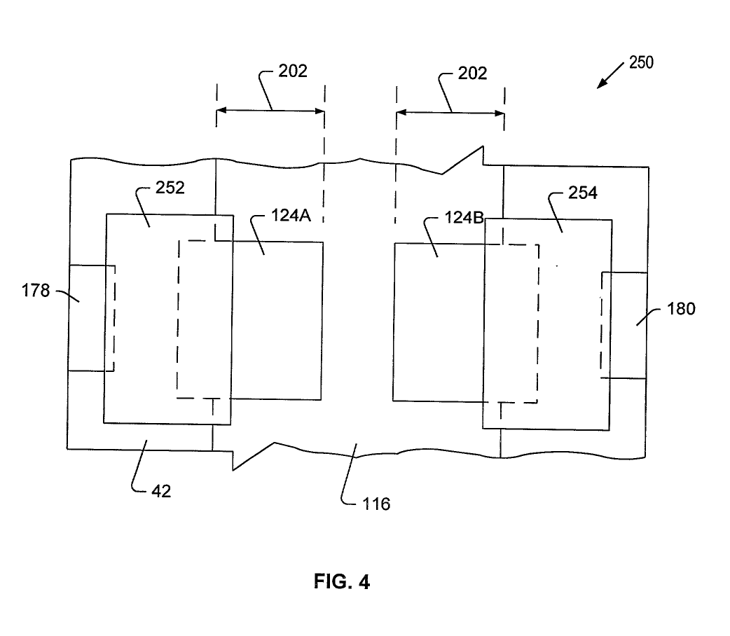

FIG. 4 shows a top view of a completed high coupling ratio flash memory device manufactured in accordance with the process of the present invention as described above. The device at 250 includes two flash memory cells sharing a common source region 116. A first cell is associated with the first drain region 178 and includes floating gate 124A disposed over substrate 42 and a select gate 252 made up of conductive layer 154A (FIG. 3) and second polysilicon layer 152A (FIG. 3) disposed over a portion of the floating gate 124A and a portion of the substrate 42. A second cell is associated with the second drain region 180 and consists of a floating gate 124B disposed over the substrate 42 and a select gate 254 composed of tungsten layer 154B (FIG. 3) and second polysilicon layer 152B (FIG. 3) disposed over a portion of the floating gate 124B and a portion of the substrate 42.

Although the present invention has been particularly shown and described above with reference to a specific embodiment, it is anticipated that alterations and modifications thereof will no doubt become apparent to those skilled in the art. It is therefore intended that the following claims be interpreted as covering all such alterations and modifications as fall within the true spirit and scope of the invention.

What is claimed is:

1. A method of fabricating a flash memory device including an array of split gate cells, comprising the steps of:
providing a silicon substrate having a top surface;
implanting ions into a predefined area of said substrate to form a common source region of said substrate;
forming at least one floating gate over said substrate, each said floating gate being associated with one of the cells and having a portion which overlies a portion of said common source region, the overlying portion of each floating gate providing for a high coupling ratio for the associated flash cell;
forming a select gate over at least a portion of each said floating gate; and
forming a drain region associated with each said cell.

2. A method of fabricating a flash memory device as recited in claim 1, wherein said step of implanting a common source region on said substrate includes the steps of:
patterning a photoresist disposed over said substrate to substantially define said predefined area at which the common source region is to be formed;
implanting said ions into said substrate to form said common source region of said substrate using said patterned photoresist as an implant mask; and
removing said patterned photoresist.

3. A method of fabricating a flash memory device as recited in claim 2, wherein said ions include arsenic ions.

4. A method of fabricating a flash memory device as recited in claim 1, wherein said step of implanting ions into a region of said substrate includes the steps of:
forming a sacrificial oxide layer over said top surface of said substrate;
patterning a photoresist disposed over said substrate to substantially define said predefined area at which the common source region is to be formed;
implanting said ions into said substrate to form said common source region of said substrate using said patterned photoresist as an implant mask; and
removing said patterned photoresist and said sacrificial oxide layer.

5. A method of fabricating a flash memory device as recited in claim 1, wherein said step of forming at least one floating gate over said substrate includes the steps of:
forming a tunneling oxide layer over the exposed top surface of said substrate;
depositing a first polysilicon layer over said tunneling oxide layer;
depositing a nitride masking layer over said first polysilicon layer;
patterning and etching said nitride masking layer to expose at least one first portion and at least one second portion of said first polysilicon layer, said first and second exposed portions substantially defining first and second floating gate regions;
forming a floating gate oxide layer over said first and second exposed portions of said first polysilicon layer;
removing said nitride masking layer;
etching said first polysilicon layer and said tunneling oxide layer using said floating gate oxide layer as a mask leaving remaining portions of said first polysilicon layer and said tunneling oxide layer disposed beneath said floating gate oxide layer, and exposing a portion of said substrate, each said remaining portion of said first polysilicon layer forming one of said floating gates associated with said cell and having side walls and also having a portion which overlies a portion of said common source region there by providing a high coupling ratio for an associated cell.

6. A method of fabricating a flash memory device as recited in claim 5, wherein said step of forming at least one select gate over at least a portion of said floating gate includes the steps of:
forming an insulating layer over said exposed portion of said substrate, over said floating gate oxide layer, and over said floating gates;
forming a second polysilicon layer over said insulating layer;
forming a conductive layer over said second polysilicon layer; and
removing portions of said conductive layer, said second polysilicon layer, and said insulating layer to form a plurality of select gates each having a portion overlying a portion of an associated one of said floating gates.

7. A method of fabricating a flash memory device as recited in claim 6, wherein said step of forming an insulating layer over said exposed portion of said substrate, over said floating gate oxide layer, and over said floating gates includes the steps of:
forming a first gate oxide layer over said exposed portion of said substrate, over said floating gate oxide layer, and over said floating gates;
forming a nitride layer over said first oxide layer;
performing an etching process to remove a portion of said nitride layer and leaving nitride spacers adjacent said side walls of each of said floating gates; and
forming a second gate oxide layer over said first oxide layer, over said nitride spacers and over said floating gate oxide layer.

8. A method of fabricating a flash memory device as recited in claim 6, wherein said conductive layer includes tungsten.

9. A method of fabricating a flash memory device as recited in claim 1, wherein said ions includes Boron ions.

10. A method of fabricating a flash memory device as recited in claim 6, wherein said step of forming a drain region associated with each cell includes the step of:
patterning and etching said conductive layer and portions of said substrate to substantially define the boundaries of at least one drain area of said substrate; and
implanting ions into said drain area of said substrate to form at least one drain region.

11. A method of fabricating a flash memory device as recited in claim 4, wherein said step of implanting said ions into said substrate to form said common source region of said substrate using said patterned photoresist as an implant mask includes:
implanting arsenic ions to provide a dopant density in the range of 1×10¹⁴/cm² to 5×10¹⁴/cm² and at an energy range of 80 to 150 KeV.

12. A method of fabricating a flash memory device as recited in claim 5, wherein said step of depositing a first polysilicon layer over said tunneling oxide layer includes:
depositing said first polysilicon layer at a temperature of approximately 620 degrees C. in order to form said first polysilicon layer having a thickness in the range of 500 to 2500 angstroms.

13. A method of fabricating a flash memory device as recited in claim 12, wherein said first polysilicon layer includes SiH4.

14. A method of fabricating a flash memory device having a high coupling ratio, comprising the steps of:
providing a silicon substrate having a top surface;
forming a sacrificial oxide layer over said top surface of said substrate;
patterning a photoresist layer disposed over said sacrificial oxide layer to substantially define a source region of the substrate;
implanting first ions into said substrate to form a common source region of said substrate using the patterned photoresist layer as an implant mask;
removing said patterned photoresist layer and said sacrificial oxide layer to expose said top surface of said substrate;
forming a tunneling oxide layer over the exposed top surface of said substrate;
depositing a first polysilicon layer over said tunneling oxide layer;
depositing a nitride masking layer over said first polysilicon layer;
patterning and etching said nitride masking layer to expose at least one first portion and at least one second portion of said first polysilicon layer, said first and second exposed portions substantially defining first and second floating gate regions;
forming a floating gate oxide layer over said first and second exposed portions of said first polysilicon layer;
removing said nitride masking layer;
etching said first polysilicon layer and said tunneling oxide layer using said floating gate oxide layer as a mask leaving remaining portions of said first polysilicon layer and said tunneling oxide layer disposed beneath said floating gate oxide layer, and exposing a portion of said substrate, each said remaining portion of said first polysilicon layer forming a floating gate associated with a cell and having side walls and also having a portion which overlies a portion of said common source region there by providing a high coupling ratio for an associated cell;
forming a first gate oxide layer over said exposed portion of said substrate, over said floating gate oxide layer, and over said floating gates;
forming a nitride layer over said first oxide layer;
performing an etching process to remove a portion of said nitride layer and leaving nitride spacers adjacent said side walls of each of said floating gates;
forming a second gate oxide layer over said first oxide layer, over said nitride spacers and over said floating gate oxide layer
forming a second polysilicon layer over said second gate oxide layer;
forming a conductive layer over said second polysilicon layer;
removing portions of said conductive layer, said second polysilicon layer, said second gate oxide layer, said nitride spacers and said first gate oxide layer to form a plurality of select gates each having a portion overlying a portion of an associated one of said floating gates; and
patterning and etching said conductive layer to expose portions of said substrate to substantially define the boundaries of at least one drain area of said substrate; and
implanting second ions into said drain area of said substrate to form at least one drain region.

15. A method of fabricating a flash memory device having a high coupling ratio as recited in claim 14, further including the step of:
implanting additional ions into portions of said substrate defined by said first and second floating gate regions, in order to adjust the threshold voltage of the flash memory cells.

16. A method of fabricating a flash memory device as recited in claim 15, wherein said first ions include N-type ions and said additional ions include P-type ions, whereby threshold voltages of the flash memory cells are adjusted.

17. A flash memory device having a high coupling ration formed in accordance with a process, comprising the steps of:
providing a silicon substrate having a top surface;
implanting ions into a predefined area of said substrate to form a common source region of said substrate;
forming at least one floating gate over said substrate, each said floating gate being associated with one of the cells and having a portion which overlies a portion of said common source region, the overlying portion of each floating gate providing for a high coupling ratio for the associated flash cell;
forming a select gate over at least a portion of each said floating gate; and
forming a drain region associated with each said cell..

18. A flash memory device having a high coupling ration as recited in claim 17, formed in accordance with a process, including the step of:
implanting additional ions into portions of said substrate defined by said first and second floating gate regions, in order to adjust the threshold voltage of the flash memory cells.

19. A flash memory device having a high coupling ration as recited in claim 17, formed in accordance with a process, including the steps of:
patterning a photoresist disposed over said substrate to substantially define said predefined area at which the common source region is to be formed;
implanting said ions into said substrate to form said common source region of said substrate using said patterned photoresist as an implant mask; and
removing said patterned photoresist.

20. A flash memory device having a high coupling ration as recited in claim 17, formed in accordance with a process, including the steps of:
forming a tunneling oxide layer over the exposed top surface of said substrate;
depositing a first polysilicon layer over said tunneling oxide layer;
depositing a nitride masking layer over said first polysilicon layer;
patterning and etching said nitride masking layer to expose at least one first portion and at least one second portion of said first polysilicon layer, said first and second exposed portions substantially defining first and second floating gate regions;
forming a floating gate oxide layer over said first and second exposed portions of said first polysilicon layer;
removing said nitride masking layer;
etching said first polysilicon layer and said tunneling oxide layer using said floating gate oxide layer as a mask leaving remaining portions of said first polysilicon layer and said tunneling oxide layer disposed beneath said floating gate oxide layer, and exposing a portion of said substrate, each said remaining portion of said first polysilicon layer forming one of said floating gates associated with said cell and having side walls and also having a portion which overlies a portion of said common source region there by providing a high coupling ratio for an associated cell.
